(19) United States
(12) Patent Application Publication
(10) Pub. No.: US 2011/0057922 A1
(43) Pub. Date: Mar. 10, 2011

(54) DRIVE DEVICE AND DISPLAY DEVICE

(75) Inventors: Tsukasa YASUDA, Kanagawa (JP); Ichiro MATSUMOTO, Kanagawa (JP); Satoru MATSUDA, Kanagawa (JP)

(73) Assignee: RENESAS ELECTRONICS CORPORATION, Kanagawa (JP)

(21) Appl. No.: 12/875,424

(22) Filed: Sep. 3, 2010

(30) Foreign Application Priority Data
Sep. 8, 2009 (JP) 2009-206658

(51) Int. Cl. G06F 3/038; H03F 3/68

(52) U.S. Cl. 345/212; 330/295

(57) ABSTRACT

A drive device according to the present invention includes a plurality of output amplifier circuits that are connected in parallel, a bias wire that supplies a bias voltage from a bias voltage supply source to the plurality of output amplifier circuits, a power supply wire that supplies a power supply voltage from a power supply voltage supply source to the plurality of output amplifier circuits, and a correction unit that superposes an offset voltage on the bias voltage so that a voltage difference between the power supply voltage and the bias voltage supplied to the plurality of output amplifier circuits is to be desirable.

### INCORPORATION BY REFERENCE

This application is based upon and claims the benefit of priority from Japanese patent application No. 2009-206658, filed on Sep. 8, 2009, the disclosure of which is incorporated herein in its entirety by reference.

### BACKGROUND

1. Field of the Invention

The present invention relates to a drive device including a plurality of output amplifier circuits, and a display device mounted with the drive device.

2. Description of Related Art Japanese Unexamined Patent Application Publication No. 2005-150215 suggests a method to eliminate influence of a power supply voltage drop generated in a circuit disposed in a semiconductor integrated circuit apparatus and to suppress an operation failure and operation speed reduction of the circuit. FIG. 7 is a circuit block diagram of the semiconductor integrated circuit apparatus disclosed in Japanese Unexamined Patent Application Publication No. 2005-150215. A semiconductor integrated circuit apparatus 200 includes a power supply terminal 112, a ground terminal (ground pad) 114, and a negative power supply terminal 116. The power supply terminal 112 is connected to an external power supply, and supplied with a power supply voltage (Vdd). The ground terminal 114 is connected to ground (0 V). The negative supply terminal 116 is connected to an external negative supply, and supplied with a negative supply voltage (−Vdd).

A power supply wire 118 is connected to the power supply terminal 112. A ground wire 120 is connected to the ground terminal 114. A plurality of circuits, from a first circuit 301 to a fth circuit 30f, are connected in parallel between the power supply wire 118 and the ground wire 120, in the order of the circuits closest to the power supply and the ground to furthest.

A current source 122 is disposed as a current generation unit between a node Gf, which is on the ground wire 120 side of the fth circuit 30f disposed in the furthest area from the ground, and the negative power supply terminal 116. That is, the current source 122 is disposed in the furthest wiring part from the ground terminal (ground pad) 114 which supplies a ground potential (0V) to the ground wire 120. The current source 122 generates a current so that the current flowing to the ground wire 120 will be the direction from ground to the negative power supply (current source 122).

By disposing the current source 122 connected to the negative power supply, the direction of the current flowing in the ground wire 120 will be the direction from ground to the node Gf. Further, the potentials of the nodes on the ground wire 120 gradually reduce as the node (in order G1, G2 . . . , and Gf) distance away from the ground and reaches their minimum at the node Gf. Further, the potentials of the nodes on the power supply wire 118 are smaller as the node distance away from the power supply (in order of V1, V2 . . . , and Vf). Thus it is possible to ensure an enough potential difference between the power supply side node and the ground side node in each of the circuits 301 to 30f, thereby achieving a stable circuit in which the voltage level does not reduce even if the circuit is disposed at a position away from the power supply (ground), and not susceptible to the influence of the power supply drop and the ground voltage increase.

In recent years, a liquid crystal display device used for a television and display for personal computer is increasing its screen size, has higher resolution, and multifunctionalized. In connection with this, the number of outputs of a source driver (drive device) for driving a liquid crystal display panel increases, and the configuration of the liquid crystal display panel is becoming complicated.

### SUMMARY

If the power supply wire and the ground wire routing disposed in the source driver causes the resistance to be high, the supply voltage gradually reduces in the circuit disposed as the distance away from the power supply voltage supply source. Further, if the power consumption is saved or the power supply is reduced so as to speed up the circuit, the supply voltage is gradually reduced in the circuit disposed as the distance away from the power supply voltage supply source. The voltage drop of the supply voltage causes an operation failure of the circuit, an operating speed reduction, and variation in slew rate (driving capability) between the output amplifier circuits, thereby generating a poor display image quality.

The recent source driver that responds to multiple outputs has a layout in which nearly thousand output amplifiers are arranged in the lengthwise direction of the liquid crystal display panel. In such configuration, a supply voltage drop in the output amplifier circuit disposed at the position away from the power supply voltage source can be especially serious.

If the technique of Japanese Unexamined Patent Application Publication No. 2005-150215 is applied, the difference between the power supply voltage and GND in an internal circuit can be corrected as described above. However, the present inventors have found a problem that the technique disclosed in Japanese Unexamined Patent Application Publication No. 2005-150215 is not able to solve the problem of variations generated in the driving capability of the output amplifier circuit disposed at the position away from the power supply voltage supply source and the output amplifier circuit disposed at the position close to the power supply voltage supply source.

A drive device according to the present invention includes a plurality of output amplifier circuits that are connected in parallel, a bias wire that supplies a bias voltage from a bias voltage supply source to the plurality of output amplifier circuits, a power supply wire that supplies a power supply voltage from a power supply voltage supply source to the plurality of output amplifier circuits, and a correction unit that superposes an offset voltage on the bias voltage so that a voltage difference between the power supply voltage and the bias voltage supplied to the plurality of output amplifier circuits is to be desirable.

The drive device according to the present invention can achieve desired driving capability in the plurality of output amplifier circuits connected in parallel by the correction unit that corrects the bias voltage in order to have a desired voltage difference between the power supply voltage and the bias voltage which are supplied to the output amplifier circuits.

The display device according to the present invention includes the above-mentioned drive device mounted thereon.

The present invention produces an exemplary advantage providing the drive device and the display device that can realize desired driving capability in the plurality of output circuits connected in parallel.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a schematic plan view of an active matrix driven liquid crystal display;

FIG. 2 is a circuit diagram illustrating an example of an output amplifier circuit of a source driver according to a first exemplary embodiment;

FIG. 3A is an outline circuit diagram for explaining a correction unit that corrects a bias voltage in the source driver according to the first exemplary embodiment;

FIG. 3B is a conceptual diagram of bias voltage correction according to the first exemplary embodiment;

FIG. 4 is an explanatory view illustrating a voltage difference between a power supply voltage and the bias voltage of the source driver according to the first exemplary embodiment;

FIG. 5A is an outline circuit diagram for explaining a correction unit which corrects the bias voltage in the source driver according to a second exemplary embodiment;

FIG. 5B is a conceptual diagram of bias voltage correction according to the second exemplary embodiment;

FIG. 6 is a timing chart of an offset signal according to the second exemplary embodiment;

FIG. 7 is circuit configuration diagram of the semiconductor integrated circuit device disclosed in Japanese Unexamined Patent Application Publication No. 2005-150215;

FIG. 8 is an outline circuit diagram for explaining a correction unit which corrects the bias voltage in the source driver according to a comparative example;

FIG. 9A is a correlation diagram illustrating the relationship of the voltage difference between an ideal power supply voltage and the bias voltage;

FIG. 9B is a correlation diagram illustrating the relationship of the voltage difference between the power supply voltage and the bias voltage according to a comparative example;

FIG. 10 is a conceptual diagram for explaining variation in output delay between output amplifier circuits; and

FIG. 11 is an explanatory diagram illustrating the voltage difference between the power supply voltage and the bias voltage according to Japanese Unexamined Patent Application Publication No. 2005-150215.

### DETAILED DESCRIPTION OF THE EXEMPLARY EMBODIMENTS

An example of the exemplary embodiments incorporating the present invention is explained hereinafter. Other exemplary embodiments are included in the scope of the present invention as long as they fall within the spirit of the present invention. The size and the ratio of each member in the following drawings are illustrated only for the convenience of explanation, and are different from the actual size and ratio.

### First Exemplary Embodiment

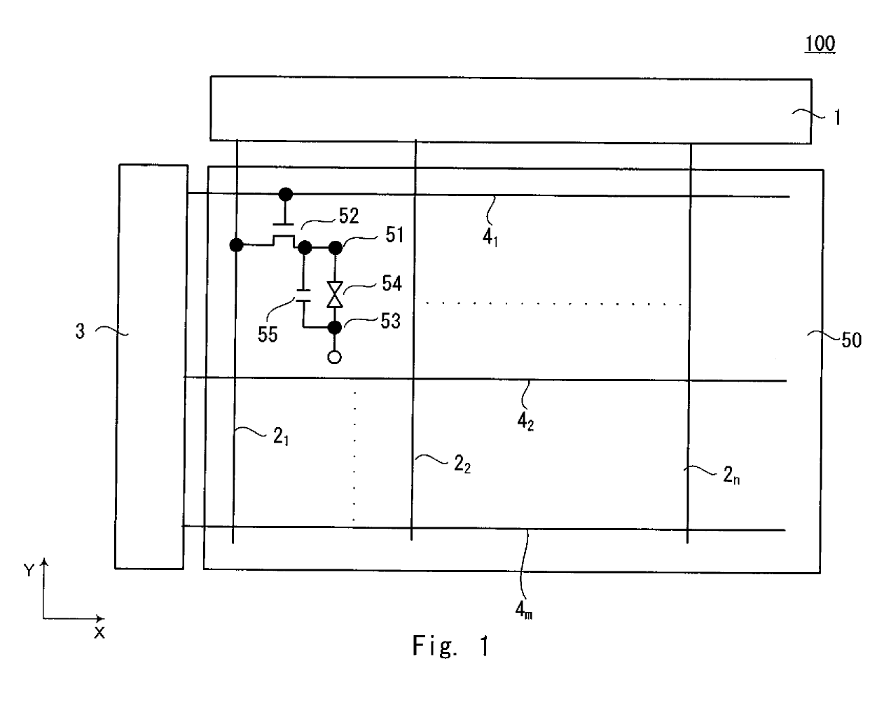

As a display device, an active matrix driven liquid crystal display device is explained as an example. FIG. 1 is a schematic explanatory diagram of the active matrix driven liquid crystal display device. In FIG. 1, an equivalent circuit diagram schematically illustrates the main configuration connected to one pixel of a display area 50.

An active matrix driven liquid crystal display 100 has a configuration in which a liquid crystal layer is sandwiched between an array substrate and an opposing substrate. As for the array substrate, a transparent pixel electrode 51 and a thin film transistor (hereinafter referred to as TFT) 52 are usually arranged in a matrix in the display area 50. One transparent common electrode 53 is formed to the entire surface of the opposing substrate. The liquid crystal is capacitive and forms a liquid crystal capacitance 54 between the pixel electrode 51 and the common electrode 53. In order to help with amount of capacitance of the liquid crystal, the liquid crystal often further includes an auxiliary capacity 55. Note that the common electrode 53 may be disposed over the array substrate.

A scanning signal controls to turn on and off the TFT 52. When the TFT 52 is turned on, a halftone signal voltage corresponding to a video data signal is applied to the pixel electrode 51, and the transmittance of the liquid crystal changes by a potential difference between each pixel electrode 51 and common electrode 53. The liquid crystal capacitance 54 and the auxiliary capacitance 55 hold the abovementioned potential difference for a certain period even after the TFT 52 is turned off, then an image is displayed.

Source lines 2 (2₁, 2₂ . . . , and 2ₙ) which transmit a plurality of level voltages (halftone signal voltages) applied to each pixel electrode 51 and gate lines 4 (4₁, 4₂, . . . , and 4ₘ) which transmits the scanning signal are arranged in a lattice. In the example of FIG. 1, the source lines 2 extend in a Y direction, and are arranged in a X direction. On the other hand, the gate lines 4 extend in the X direction, and are arranged in the Y direction. The gate lines 4 and source lines 2 are large capacitive loads by the capacitance generated in intersections therebetween, and the liquid crystal capacitance 54 sandwiched between the common electrodes.

The source lines 2 extend to a source driver 1, which is a drive device (driver LSI (Large Scale Integration)) disposed in a frame area sectioned outside the display area 50. Similarly, the gate lines 4 extend to a gate driver 3, which is a drive device disposed in the frame area. Necessary clocks CLK, control signals, and power supply voltage are respectively supplied from a display controller (not shown) to the source driver 1 and the gate driver 3. Further, video data is supplied to the source driver 1 from the display controller.

Data of one pixel is rewritten in one frame period ( 1/60 second). In each gate line, pixels are sequentially selected one by one (by each line) and supplied with a halftone signal voltage from each source line within a selection period. The gate driver 3 should supply at least a binary scanning signal. On the other hand, the source driver 1 needs to drive the source lines 2 by the level of the halftone signal voltage corresponding to the number of halftone. Therefore, the source driver 1 includes decoders for converting video data to halftone signal voltage, and output amplifier circuits for amplifying and outputting the halftone signal voltage to the source lines 2. The decoders and the output amplifier circuits are provided to each of the source lines 2.

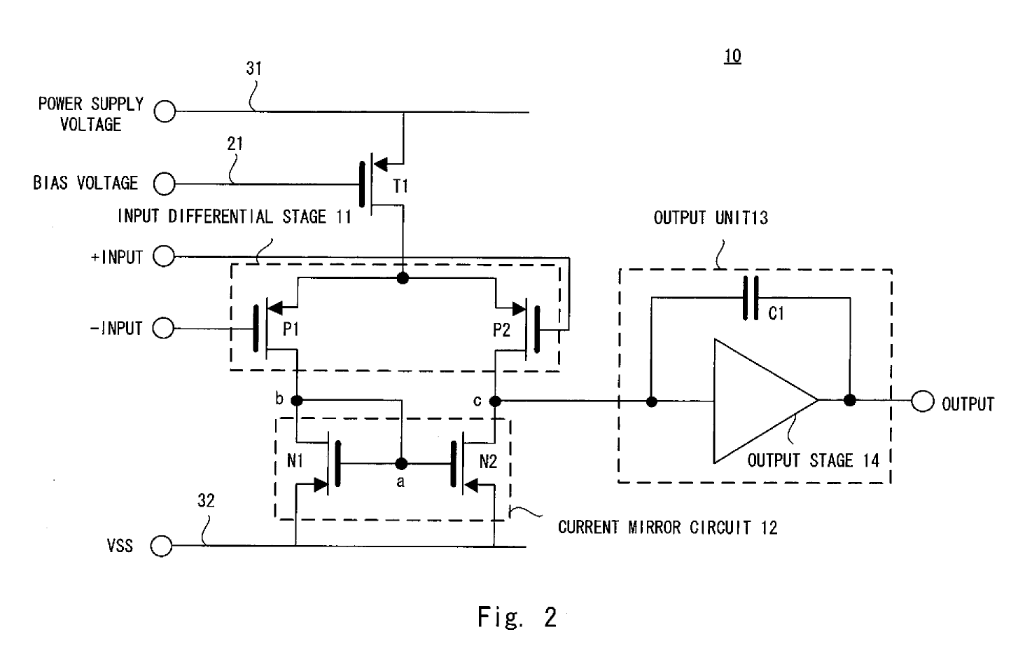

FIG. 2 illustrates an example of the circuit diagram of the output amplifier circuit 10 disposed in the source driver 1. As mentioned above, the output amplifier circuits 10 are disposed for each of the source lines 2. However in FIG. 2, only one output amplifier circuit 10 is illustrated.

The each output amplifier circuit 10 includes a current source transistor T1, an input differential stage 11 which functions as a differential stage, a current mirror circuit 12, and an output unit 13. Further, the each output amplifier circuit 10 is supplied with a power supply voltage via a power supply wire 31 and a bias voltage via a bias supply line 21. Furthermore, the each output circuit 10 is configured to receive a ground voltage (Vss) via a VSS wire 32.

A P-type MOS transistor is disposed as the current source transistor T1 according to the first exemplary embodiment. It is needless to say that the transistor may be N-type. The bias voltage is supplied to the gate of the current source transistor T1 via the bias supply line 21. The power supply voltage is supplied to the source of the current source transistor T1 via the power supply wire 31. The drain of the current source transistor T1 is connected to the input differential stage 11.

A first differential transistor and a second differential transistor of a first conductivity type that function as a pair transistor are disposed in the input differential stage 11. In the first exemplary embodiment, a P-type MOS transistor is used as the first differential transistor (hereinafter referred to as a first differential transistor P1) and a P-type MOS transistor is used as the second differential transistor (hereinafter referred to as a second differential transistor P2). The paired transistor is not limited to P-type but may be N-type.

The current mirror circuit 12 is an intermediate stage connected to the input differential stage 11, and functions as an active load unit. A first intermediate transistor and a second intermediate transistor of the second conductivity type are disposed in the current mirror circuit 12. In the first exemplary embodiment, an N-type MOS transistor is used as the first intermediate transistor (hereinafter referred to as a first intermediate transistor N1), and an N-type MOS transistor is used as the second intermediate transistor (hereinafter referred to as a second intermediate transistor N2). The first intermediate transistor N1 and the second intermediate transistor N2 which are formed in the current mirror function as active loads of the differential pair, and convert an input differential signal into a single-ended signal.

The output unit 13 is connected to a junction between the input differential stage 11 and the current mirror circuit 12, and includes an output stage 14 and a phase compensation capacitance C1. The phase compensation capacitance C1 is connected before and after the output stage 14.

The sources of the first differential transistor P1 and the second differential transistor P2 are connected in common. Then, these commonly connected sources are connected to the drain of the current source transistor T1. The drain of the first differential transistor P1 is connected to the drain of the first intermediate transistor N1, Similarly, the drain of the second differential transistor P2 is connected to the drain of the second intermediate transistor N2.

The gate electrode (control terminal) of the first differential transistor P1 is connected to an inverting input terminal (−). The gate electrode (control terminal) of the second differential transistor P2 is connected to a non-inverting input terminal (+).

The sources of the first intermediate transistor N1 and the second intermediate transistor N2 are connected to the ground voltage VSS. The gates of the first intermediate transistor N1 and the second intermediate transistor N2 are connected in common with a node a. The node a is connected to a node b, which is positioned between the drain of the first differential transistor P1 and the drain of the first intermediate transistor N1.

A node c positioned between the drains of the second differential transistor P2 and the second intermediate transistor N2 is connected to the output stage 14 of the output unit 13. The output by the output amplifier circuit 10 is transmitted to the source line 2 from the output stage 14.

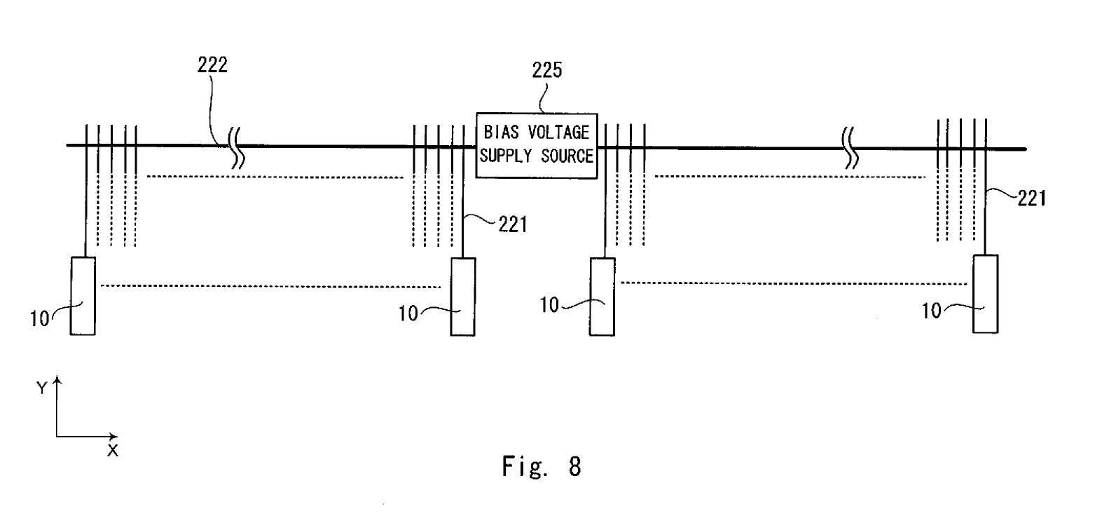

The source driver according to the comparative example is explained below. FIG. 8 illustrates the comparative example of a supply path of the bias voltage supplied to the output amplifier circuit 10 illustrated in FIG. 2. The bias voltage is supplied to the gate of the current source transistor T (not shown) of each output amplifier circuit 10 via trunk bias wires 222 and bias power supply lines 221 from a bias voltage source supply 225 disposed in the source driver.

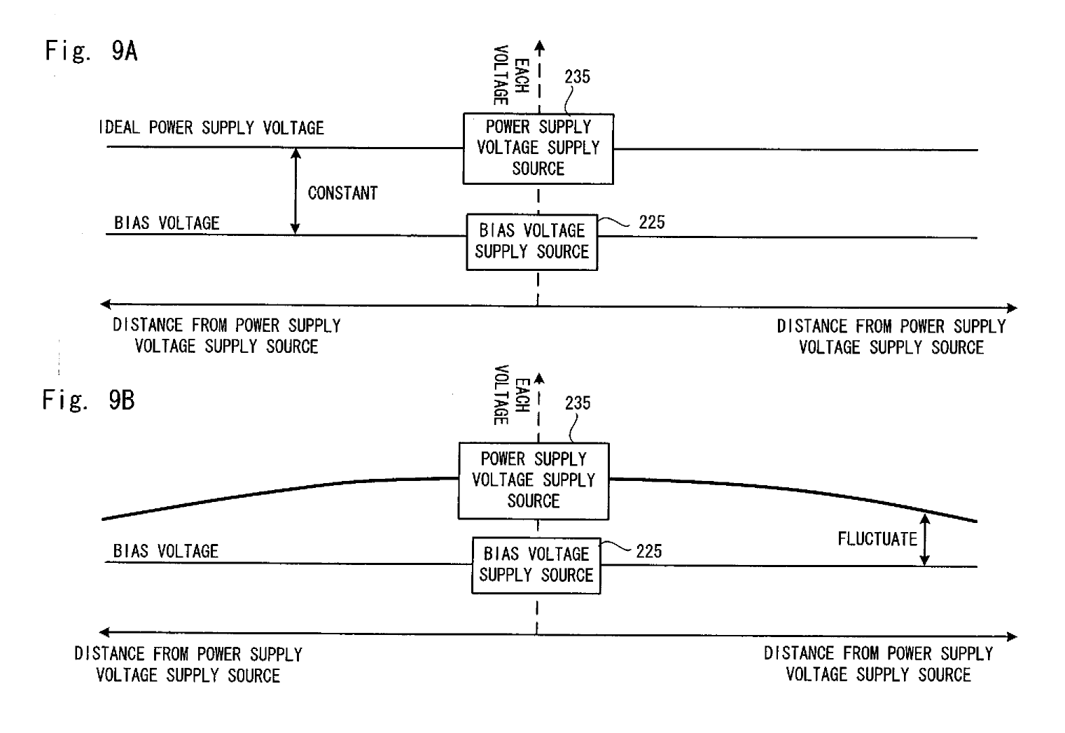

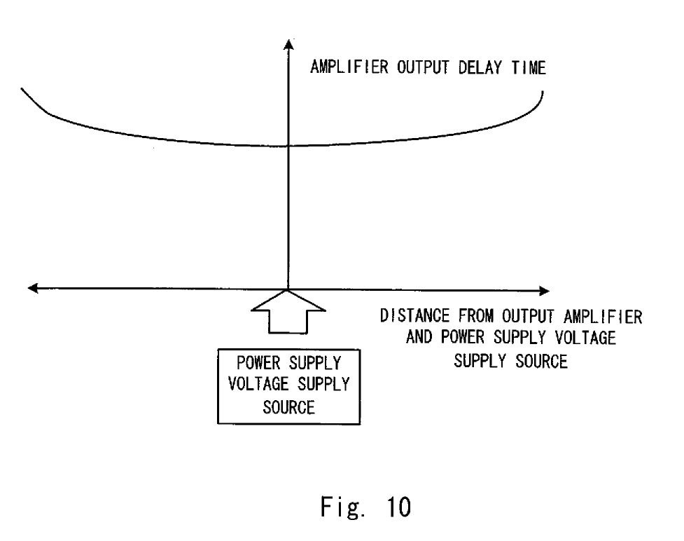

The bias voltage source supply 225 (see FIG. 8) and a power supply voltage source supply (not shown) are disposed in almost a central area of the source driver. The trunk bias wires 222 extends in the both sides of the X direction of FIG. 8 from the bias voltage supply source 225 disposed at almost center of the source driver to the left and right edge parts of the source driver. Then, the bias power supply lines 221 corresponding to the source lines are branched from the trunk bias lines 222. The bias power supply lines 221 are disposed as corresponding to the output amplifier circuits 10. Next, the driving capability of the output amplifier circuits of the source driver is explained. As illustrated in FIG. 9A, the voltage difference between the power supply voltage and the bias voltage which are supplied to the plurality of output amplifier circuits connected in parallel is desirably constant at any time regardless of the distance of separation from a power supply voltage supply source 235 and the bias voltage supply source 225. However, driving the output amplifier circuits 10 consumes a large amount of current, thus a temporal power supply voltage drop (so-called an IR drop) occurs due to the relationship of wiring resistance of the current and the power supply. On the other hand, the bias voltage which does not consume current indicates an almost fixed potential. Therefore, in reality, the relationship of the voltage difference between the power supply voltage and the bias voltage will not be the one as illustrated in FIG. 9A but will be the one illustrated in FIG. 9B. In the current source transistor T1 of the output amplifier circuit 10 as the one illustrated in FIG. 2, if the voltage difference between source and gate (Vgs) falls, the driving capability of the output amplifier circuit is notably degraded. This tendency becomes more remarkable as the output amplifier circuit distance away from the power supply voltage supply part whereby the current consumption is accumulated. As a result, the output of the output amplifier circuit with degraded driving capability will result in the output delay distribution as illustrated in FIG. 10. Then, a display image quality failure such as a write failure is generated at the position away from the power supply voltage supply source in the source drive.

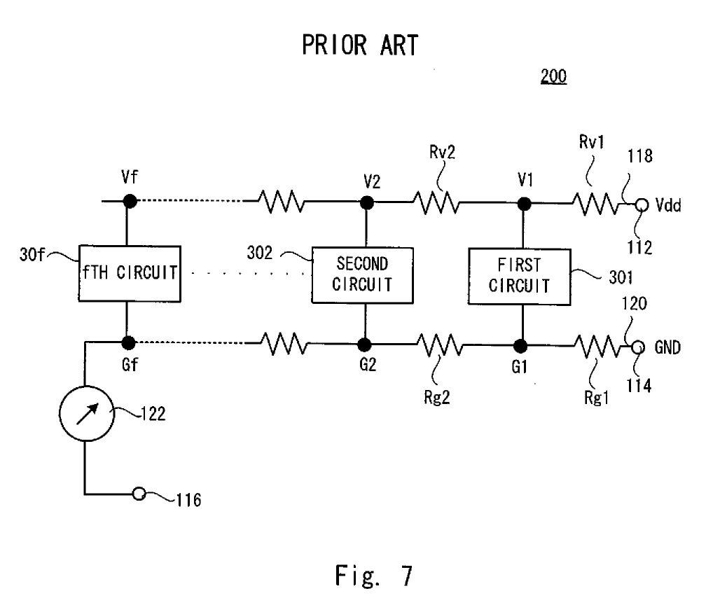

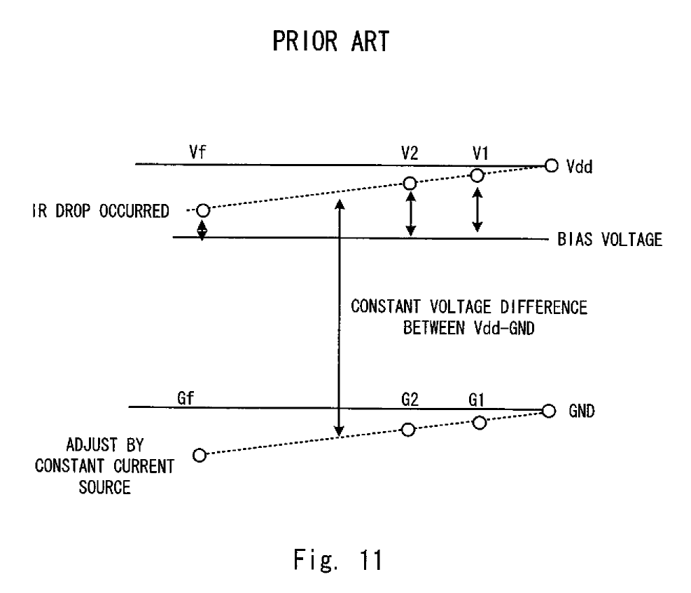

In Japanese Unexamined Patent Application Publication No. 2005-150215, as described above, the voltage difference between the power supply voltage and GND in the internal circuits 301 to 30f can be corrected (see FIG. 7). However, as illustrated in FIG. 11, the voltage difference between the bias voltage and the power supply voltage cannot be corrected. Moreover, Japanese Unexamined Patent Application Publication No. 2005-150215 requires another power supply less than or equal to GND, and a current source of opposite direction must be disposed inside the circuit.

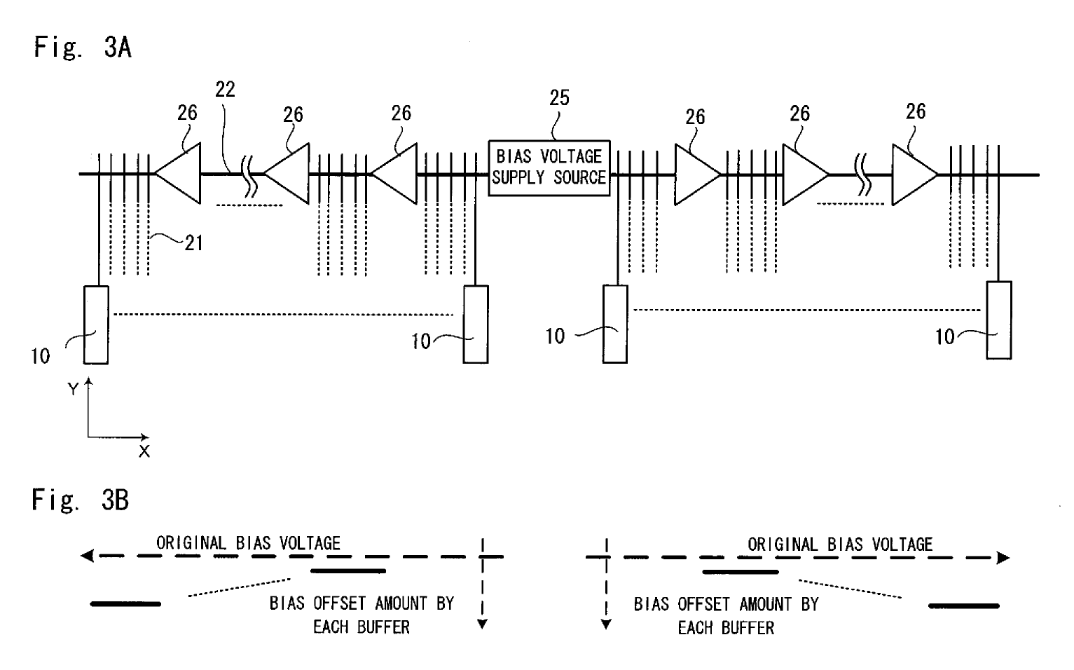

Next, features of the first exemplary embodiment are explained. FIG. 3A illustrates an example of a supply path of the bias voltage supplied to the output amplifier circuits 10. The bias voltage is supplied to the gate of the current source transistor T1 of each output amplifier circuit 10 via the trunk bias wire 22 which functions as a bias wire, and the bias power supply line 21 which similarly functions as a bias wire from the bias voltage source supply 25 disposed in the source driver 1.

As illustrated in FIG. 3A, the bias voltage source supply 25 is disposed in almost the center area of the source driver 1. The trunk bias wires 22 extend in the both sides of the X direction of FIG. 3A from the bias voltage supply source 25 disposed at almost center of the source driver 1 to the left and right edge parts of the source driver 1. Then, the bias power supply lines 21 corresponding to the source lines 2 are branched from the trunk bias wires 22. The bias power supply lines 21 are disposed for corresponding to the output amplifier circuits 10. The first exemplary embodiment explained the example of disposing one output amplifier circuit 10 for the bias supply line 21. However the output amplifier circuits may be disposed on the upper and lower sides in the Y direction of the bias supply lines 21 in FIG. 3A. The output amplifier circuits may be connected in series to the each bias power supply line 21.

A plurality of the buffers 26 are arranged over the trunk bias wires 22. In the first exemplary embodiment, the buffer 26 is disposed per five bias supply lines 21 disposed by the trunk bias line 22 (see FIG. 3A). The buffer 26 is responsible for superposing an offset voltage on the bias voltage in response to an input of a state signal.

FIG. 3B is a conceptual diagram of the bias voltage correction by the buffers 26. As illustrated in FIG. 3B, the bias voltage passed through the buffers 26 is offset by a predetermined amount from the original bias voltage. By providing the buffers 26, it is possible to intentionally (positionally and temporally) correct the bias voltage supplied to the output amplifier circuits 10 in the source driver 1 so that the bias voltage will comply with an amount of fluctuation and a fluctuation timing of the power supply voltage.

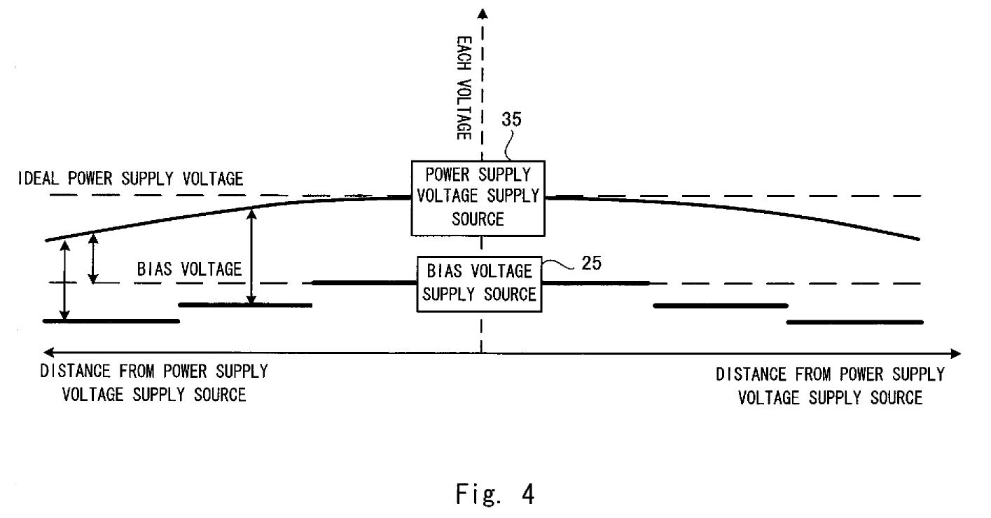

FIG. 4 is a conceptual diagram for explaining the relationship of the voltage difference between the power supply voltage and the bias voltage of the source driver 1 according to the first exemplary embodiment. In the first exemplary embodiment, a power supply voltage source supply 35 is disposed near the bias voltage source supply 25. That is, the power supply voltage supply source 35 is disposed in the central area of the source driver 1. As illustrated in FIG. 4, driving the output amplifier circuits 10 consume a large amount of current, thus a temporal power supply voltage drop (so-called an IR drop) occurs due to the relationship of wiring resistance of the current and the power supply. In other words, the power supply voltage drop by the current consumed by the output amplifier circuits 10 occur more as the output amplifier circuit 10 distance away from the power supply voltage supply source 35. On the other hand, the bias voltage which does not consume current indicates an almost fixed potential.

Therefore, the buffers 26 with the offset buffer on the way the trunk bias wires 22 to match the power supply voltage drop curve. The amount of offset voltages can be specified arbitrarily by the design of the buffers 26. Then, the bias voltage is corrected stepwise for the designed offset voltages and for the number of buffers 26. By the voltage difference between the power supply voltage and the bias voltage, it is possible to equalize the driving capability between the output amplifier circuits with different distances of separation from the power supply voltage supply source 35 and the bias voltage source supply 25.

The insertion point of the buffers 26 and the number of buffers to insert may be designed as appropriate depending on the conditions such as the power consumption of each output amplifier circuit, power supply wiring resistance in the source driver, operation usage at the time of actual use, and layout limitations. Increased number of the buffers can control the bias voltage more accurately.

In the first exemplary embodiment, by disposing the buffers 26 and offsetting the bias voltage, it is possible to maintain the voltage difference between the power supply voltage and the bias voltage even if a power supply voltage drop occurred at the time of driving the output amplifier circuits. Consequently, this enables equalization of the driving capability between the output amplifier circuits connected in parallel.

### Second Exemplary Embodiment

Next, an example of the source driver with a different configuration from the above exemplary embodiment is described. In the following explanation, the same components as the above exemplary embodiment are denoted by the same symbols, and the explanation is omitted as appropriate.

The basic configuration of a source driver according to the second exemplary embodiment is the same as the first exemplary embodiment except the following point. The point is that in the second exemplary embodiment, an external signal controls to turn on or off the offset output to the buffers. The first exemplary embodiment adopts the buffer which is not equipped with this function.

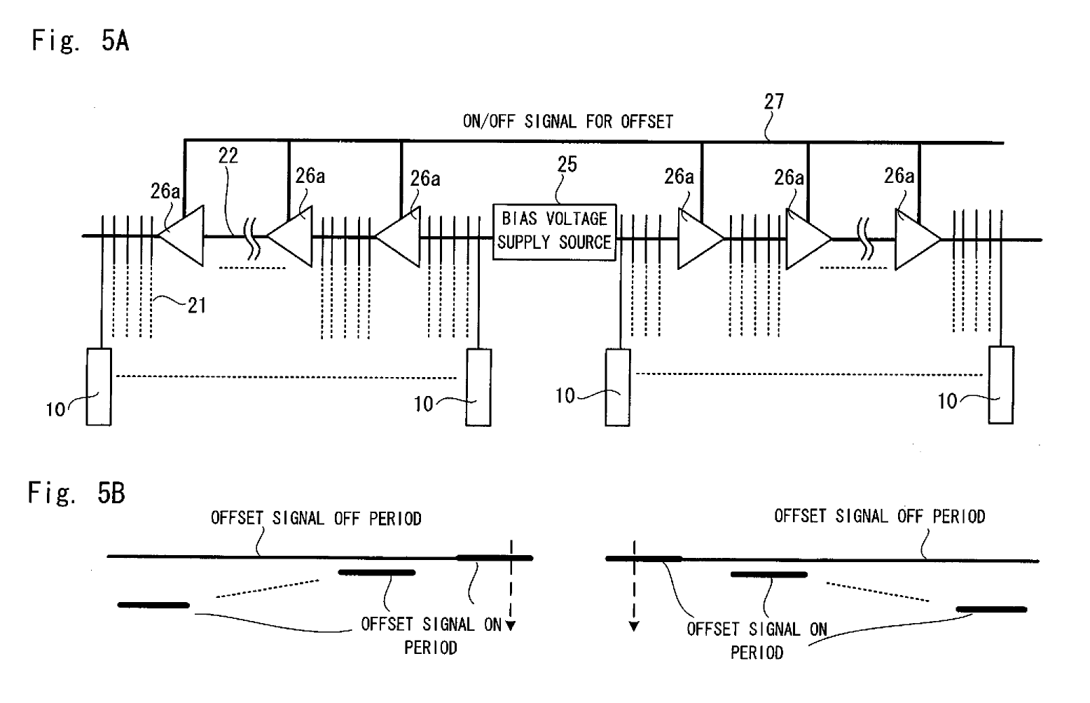

FIG. 5A illustrates an example of a supply path of the bias voltage supplied to the output amplifier circuits 10. The bias voltage is supplied to the gate of the current source transistor T1 of each output amplifier circuit 10 via the trunk bias wires 22 and the bias supply lines 21 from the bias voltage source supply 25 disposed in the source driver 1. A plurality of the buffers 26a are disposed midway of the bias power supply line 21.

Each buffer 26a has a timing adjustment function to control timings to turn on and off the offset output that is superposed on the bias voltage. To be specific, a control wire 27, which controls to turn on and off the offset output by an external signal, is connected to the buffers 26a. The control wire 27 is connected outside the source driver 1. A plurality of buffers 26a are disposed over the trunk bias wire 22. In the second exemplary embodiment, the buffer 26a is disposed per five bias supply lines 21. An external signal transmitted via the control wire 27 controls to turn on and off the offset output of the buffer 26a.

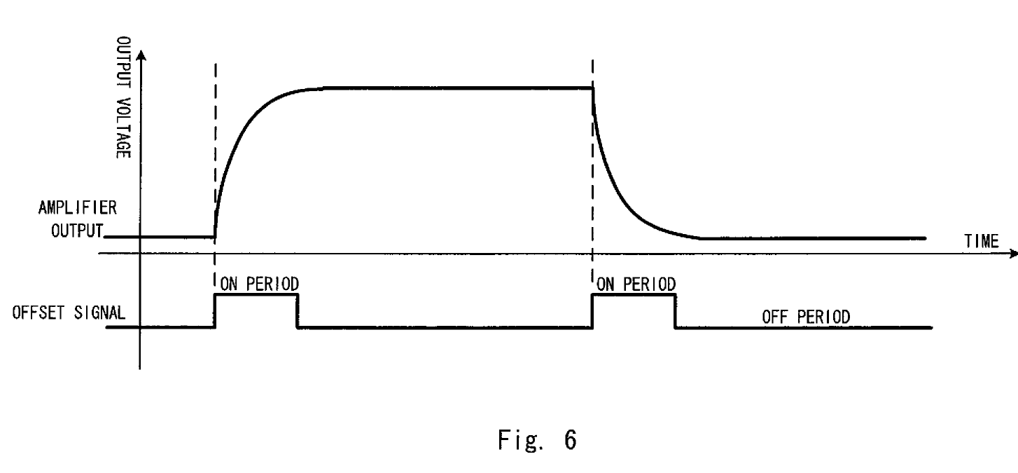

FIG. 5B is a conceptual diagram schematically illustrating the state of the bias voltage when the external signal controls to turn on and off the offset output. FIG. 6 illustrates an operation example of the offset signal applied to the buffers 26a. As illustrated in FIG. 6, the offset output of the buffers are turned on so that the bias voltage can be offset at the timing when the output by the output amplifier circuits 10 changes (the timing when a current flows to the entire drive device and the power supply voltage falls near the position away from the power supply voltage supply position). An on period of the offset output of the buffer is specified according to the output amplifier circuit capability or the size of the connected load.

By providing the buffers 26a, it is possible to intentionally (positionally and temporally) correct the bias voltage supplied to the output amplifier circuits 10 in the source driver 1 so that the bias voltage will comply with an amount of fluctuation and fluctuation timing of the power supply voltage. Further, by the configuration in which the external signal can control to turn on and off the offset output, the increase in the current consumption of the source driver 1 can be suppressed to the minimum.

The current consumed by the output amplifier circuits 10 in the source driver 1 can be roughly divided into two kinds. One is generally referred to as static current consumption. The static current consumption is the current consumption necessary to perform circuit operation, and a predetermined amount of the current is consumed whether the output amplifier circuits 10 are driven or not. Another current consumed by the output amplifier circuits 10 is referred to as active current consumption. The active current consumption flows when the output amplifier circuits 10 are driven. The active current consumption is determined by the design of the output amplifier circuits 10, the load connected to the output amplifier circuits 10, and driving conditions of the output amplifier circuits 10. The average active current consumption depends on the conditions, but will usually be several times or more of the static current consumption.

According to the second exemplary embodiment, the bias voltage is offset only in the necessary period. Thus in the period when the offset adjustment is unnecessary, which is the period when the output amplifier circuits 10 are not driven, it is possible to prevent unnecessary current consumption from increasing.

In the second exemplary embodiment, the correction unit is disposed for preventing from generating the voltage difference between the power supply voltage and the bias voltage. This enables equalization of the driving capability between the plurality of disposed output amplifier circuits. Since the buffer is used as the correction unit, it is possible to achieve an exemplary advantage that the design is easy. Further, the buffer further includes the function to turn on and off the offset output, thus the increase of the current consumption can be suppressed to the minimum.

The above first and second exemplary embodiments explained the example of providing a buffer as the correction unit. However the correction unit is not limited to the buffer as long as the unit corrects the difference between the power supply voltage and the bias voltage to be desirable. Furthermore, although the example of disposing the bias voltage supply source at the center of the source driver has been explained, it is merely an example and the position is not especially limited. For example, the bias voltage supply source may be disposed on the edge part or outside the drive device. The power supply voltage supply source may be disposed on the edge part or outside the drive device.

Additionally, the case of applying the present invention to the liquid crystal display device is explained as an example of the display device. However the present invention can be applied to other display devices such as an EL display device. Other than forming a circuit to a semiconductor chip of the drive device or the like, the drive device may be directly formed on the insulating substrate using COG (Chip On. Glass) technology. Although the source driver is explained as an example of the drive device, it is possible to widely apply the drive device to the usages to control the voltage difference between the power supply voltage and the bias voltage in the plurality of output amplifier circuits connected in parallel.

The above exemplary embodiments explained the example of equalizing the driving capability of the plurality of output amplifier circuits connected in parallel. However the present invention can be applied to the case of adjusting the driving capability to be desirable depending on the individual output amplifier circuits. In other words, the above exemplary embodiments explained the example of correcting the voltage difference between the power supply voltage and the bias voltage to be constant among the plurality of output amplifier circuits. However the present invention can be applied to the case of adjusting the voltage difference between the power supply voltage and the bias voltage to be a desirable value. The correction unit may correct the voltage difference between the power supply voltage and the bias voltage to be smaller. The example of providing the correction unit to the trunk bias wire is explained, however the correction unit may be provided on the bias supply line. Moreover, the timing adjustment function for controlling the timing to turn on and off the offset output that is superposed on the bias voltage is not limited to the example of the second exemplary embodiment but various modifications can be made within the scope of the present invention.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A drive device comprising:
a plurality of output amplifier circuits that are connected in parallel;
a bias wire that supplies a bias voltage from a bias voltage supply source to the plurality of output amplifier circuits;
a power supply wire that supplies a power supply voltage from a power supply voltage supply source to the plurality of output amplifier circuits; and
a correction unit that superposes an offset voltage on the bias voltage so that a voltage difference between the power supply voltage and the bias voltage supplied to the plurality of output amplifier circuits is to be desirable.

2. The drive device according to claim 1, wherein the correction unit is a buffer inserted midway of the bias wire, in which the buffer is for superposing the offset voltage on an output in response to an input of a state signal.

3. The drive device according to claim 1, wherein the correction unit corrects the voltage difference between the power supply voltage and the bias voltage in the plurality of output amplifier circuits to be constant.

4. The drive device according to claim 2, wherein the correction unit corrects the voltage difference between the power supply voltage and the bias voltage in the plurality of output amplifier circuits to be constant.

5. The drive device according to claim 1, wherein the correction unit includes a timing adjustment function that controls a timing to superpose the offset voltage on the bias voltage.

6. The drive device according to claim 2, wherein the correction unit includes a timing adjustment function that controls a timing to superpose the offset voltage on the bias voltage.

7. The drive device according to claim 3, wherein the correction unit includes a timing adjustment function that controls a timing to superpose an offset voltage on the bias voltage.

8. The drive device according to claim 4, wherein the correction unit includes a timing adjustment function that controls a timing to superpose an offset voltage on the bias voltage.

9. The drive device according to claim 1, wherein the correction unit offsets the bias voltage at a timing when an output of the plurality of output amplifier circuits changes.

10. The drive device according to claim 2, wherein the correction unit offsets the bias voltage at a timing when an output of the plurality of output amplifier circuits changes.

11. The drive device according to claim 3, wherein the correction unit offsets the bias voltage at a timing when an output of the plurality of output amplifier circuits changes.

12. The drive device according to claim 4, wherein the correction unit offsets the bias voltage at a timing when an output of the plurality of output amplifier circuits changes.

13. A display device that is mounted with a drive device, the drive device comprising:
a plurality of output amplifier circuits that are connected in parallel;
a bias wire that supplies a bias voltage from a bias voltage supply source to the plurality of output amplifier circuits;
a power supply wire that supplies a power supply voltage from a power supply voltage supply source to the plurality of output amplifier circuits; and
a correction unit that superposes an offset voltage on the bias voltage so that a voltage difference between the power supply voltage and the bias voltage supplied to the plurality of output amplifier circuits is to be desirable.

14. The drive device according to claim 13, wherein the correction unit is a buffer inserted midway of the bias wire, in which the buffer is for superposing the offset voltage on an output in response to an input of a state signal.

15. The drive device according to claim 13, wherein the correction unit corrects the voltage difference between the power supply voltage and the bias voltage in the plurality of output amplifier circuits to be constant.

16. The drive device according to claim 14, wherein the correction unit corrects the voltage difference between the power supply voltage and the bias voltage in the plurality of output amplifier circuits to be constant.
